(19) United States
(12) Patent Application Publication
(10) Pub. No.: US 2011/0249419 A1
(43) Pub. Date: Oct. 13, 2011

(54) CIRCUIT BOARD ASSEMBLY AND CONNECTING BRACKET THEREOF

(75) Inventor: ZHENG-HENG SUN, Tu-Cheng (TW)

(73) Assignee: HON HAI PRECISION INDUSTRY CO., LTD., Tu-Cheng (TW)

(21) Appl. No.: 12/764,055

(22) Filed: Apr. 20, 2010

(30) Foreign Application Priority Data
Apr. 7, 2010 (CN) 201010140893.1

(51) Int. Cl. H05K 1/11

(52) U.S. Cl. 361/803

(57) ABSTRACT

A circuit board assembly includes a circuit board, a daughter card, and a connecting bracket with a supporting portion. The circuit board includes a first connector and a first position element. The daughter card includes a second connector and a second position element. A first connecting portion extends down from the supporting portion, a second connecting portion extends up from the supporting portion and is electrically connected to the first connecting portion. Two position portions extend from the supporting portion. The first connector of the circuit board is connected to the first connecting portion of the connecting bracket. The second connector of the daughter card is connected to the second connecting portion of the connecting bracket. The first position element of the circuit board and the second position element of the daughter card are latched with the position portions of the connecting bracket, respectively.

### BACKGROUND

1. Technical Field

The present disclosure relates to a circuit board assembly.

2. Description of Related Art

Nowadays, many circuit boards have connectors to connect to daughter cards, such as embedded universal serial bus daughter cards. Referring to FIG. 5, a common circuit board assembly includes a circuit board 20 and a daughter card 10. A connector 12 of the daughter card 10 is plugged into a corresponding connector 22 of the circuit board 20, and then the daughter card 10 can communicate with the circuit board 20. However, when the daughter card 10 is installed on the circuit board 20, there is often not enough space remaining between the daughter card 10 and the circuit board 20 to arrange any but the elements of very small heights.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of a circuit board assembly, in accordance with an embodiment.

FIG. 2 is an inverted view of FIG. 1.

FIG. 3 is an assembled, isometric view of the circuit board assembly of FIG. 1.

FIG. 4 is an inverted view of FIG. 3.

FIG. 5 is an isometric, schematic view of a common circuit board assembly.

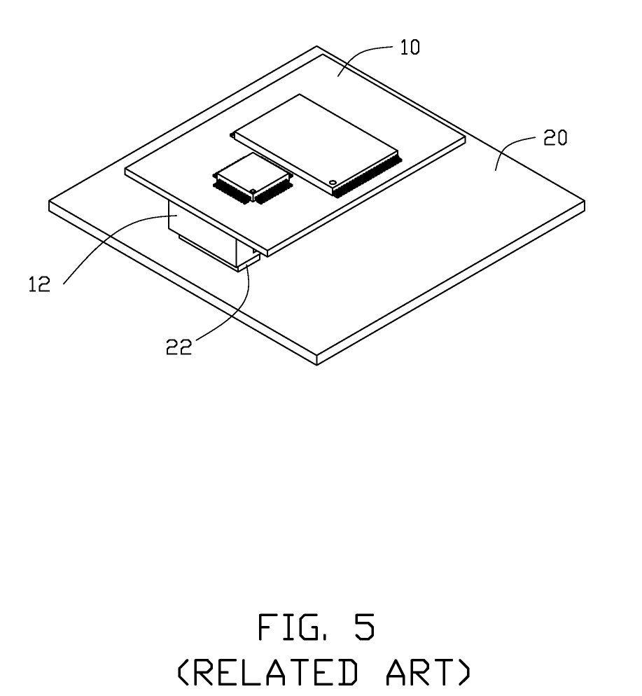

### DETAILED DESCRIPTION

The disclosure is illustrated by way of example and not by way of limitation in the figures of the accompanying drawing in which like references indicate similar elements. It should be noted that references to “an” or “one” embodiment in this disclosure are not necessarily to the same embodiment, and such references mean at least one.

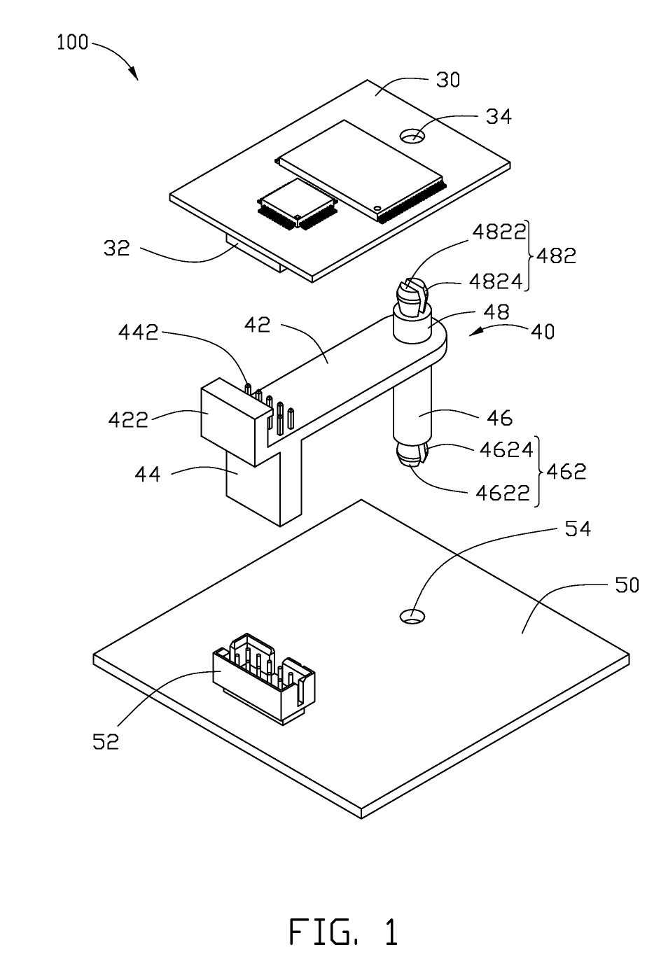

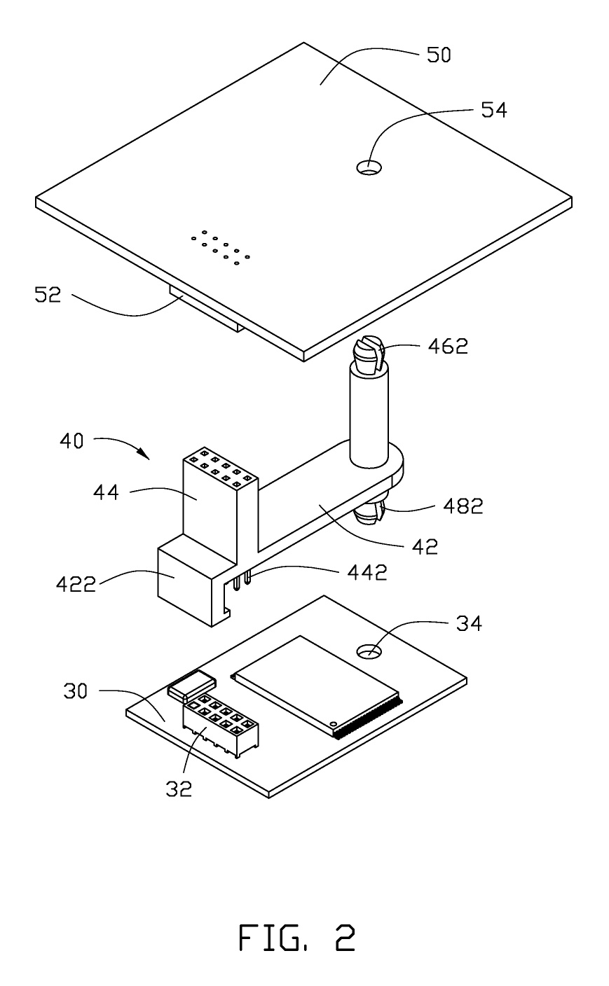

Referring to FIGS. 1 and 2, an embodiment of a circuit board assembly 100 includes a circuit board 50, a daughter card 30 such as an embedded universal serial bus daughter card, and a connecting bracket 40.

The circuit board 50 includes a connector 52. The daughter card 30 includes a connector 32 compatible with the connector 52. The daughter card 30 defines a through hole 34 apart from the connector 32. The circuit board 50 defines a through hole 54 corresponding to the through hole 34. It may be understood that the circuit board 50 also includes other circuits, such as a power circuit. These other circuits fall within well-known technologies, and are therefore not described here.

The connecting bracket 40 includes an elongated supporting portion 42. An elongated first connecting portion 44 extends downwardly from a first end of the supporting portion, and a second connecting portion 442 extends up from the first end and is electrically connected to the first connecting portion 44. The first connecting portion 44 is the same as the connector 32. The second connecting portion 442 is the same as the connector 52. An elongated cylindrical first position portion 46 extends down from a second end of the supporting portion 42 opposite to the first end, and a cylindrical second position portion 48 extends up from the second end of the supporting portion 42. A latching member 462 extends down from a distal end of the first position portion 46 away from the supporting portion 42. The latching member 462 includes two opposite elastic latching posts 4622 and 4624 with a groove (not labeled) defined between the latching posts 4622 and 4624, for being conveniently deformed. A latching member 482 extends from a distal end of the second position portion 48 opposite to the supporting portion 42. The latching member 482 includes two opposite elastic latching posts 4822 and 4824 with a groove (not labeled) defined between the latching posts 4822 and 4824, for being conveniently deformed. An L-shaped elastic fixing portion 422 extends up firstly from the first end of the supporting portion 42, and then towards the second connecting portion 442.

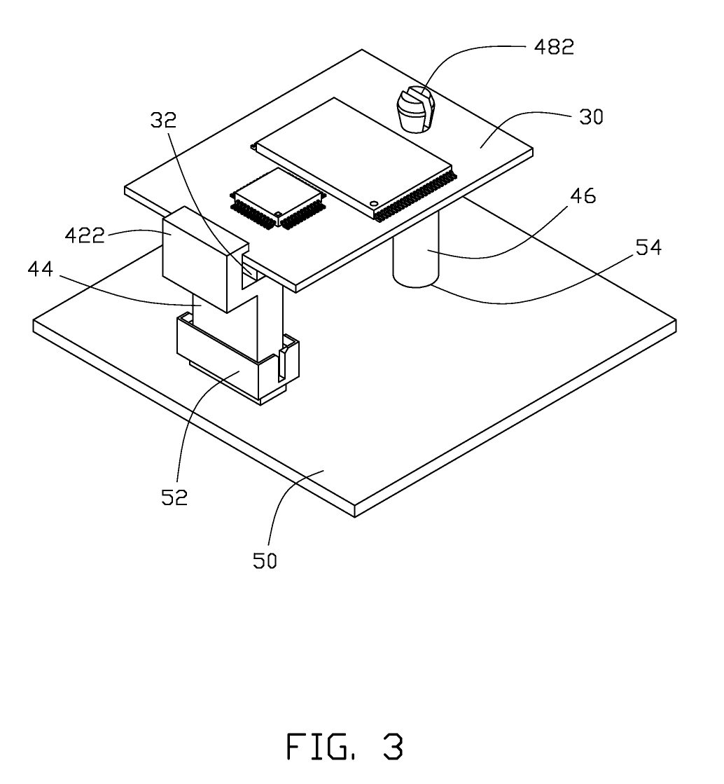

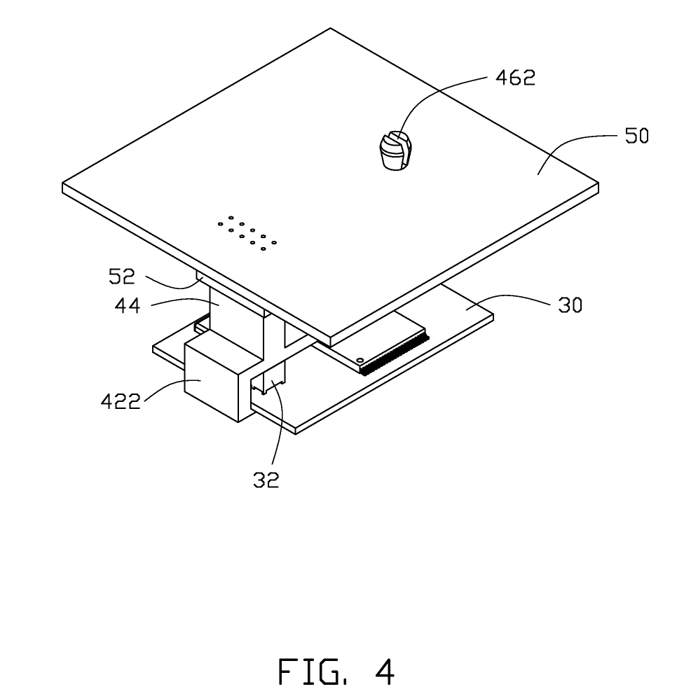

Referring to FIGS. 3 and 4, in assembly, the first connecting portion 44 of the connecting bracket 40 is connected to the connector 52 of the circuit board 50. The latching member 462 of the connecting bracket 40 is latched into the through hole 54 of the circuit board 50. Thus, the connecting bracket 40 is positioned on the circuit board 50. The connector 32 of the daughter card 30 is connected to the second connecting portion 442, and the fixing portion 422 clips an edge of the daughter card 30. The latching member 482 of the connecting bracket 40 is latched into the through hole 34 of the daughter card 30. Thus, the daughter card 30 is positioned on the connecting bracket 40. Because the first connecting portion 44 and the second connecting portion 442 of the connecting bracket 40 are electrically connected to each other, the connector 52 of the circuit board 50 is electrically connected to the connector 32 of the daughter card 30 through the connecting bracket 40. In other words, the daughter card 30 can communicate with the circuit board 50 through the connecting bracket 40. Because the first connecting portion 44 and the first position portion 46 of the connecting bracket 40 have great length, some taller elements can be arranged between the daughter card 30 and the circuit board 50.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A circuit board assembly comprising:
a circuit board comprising a first connector and a first position element;
a daughter card comprising a second connector compatible with the first connector and a second position element corresponding to the first position element; and
a connecting bracket comprising a supporting portion, wherein an elongated first connecting portion extends down from the supporting portion, and a second connecting portion extends up from the supporting portion and is electrically connected to the first connecting portion, a first position portion and a second position portion extend from the supporting portion;
wherein the first connector of the circuit board is connected to the first connecting portion of the connecting bracket, the second connector of the daughter card is connected to the second connecting portion of the connecting bracket, the first position element of the circuit board is latched with the first position portion of the connecting bracket, the second position element of the daughter card is latched with the second position portion of the connecting bracket.

2. The circuit board assembly of claim 1, wherein the first position element of the circuit board and the second position element of the daughter card are through holes respectively defined in the circuit board and the daughter card, the first and second position portions of the connecting bracket are latching members respectively extending down and up from the supporting portion to be latched in the through holes.

3. The circuit board assembly of claim 2, wherein each of the latching members comprising two opposite elastic latching posts extend from distal ends of the first and position portions of the connecting bracket, with a groove defined between the latching posts.

4. The circuit board assembly of claim 1, wherein an L-shaped elastic fixing portion extends up from an edge of the supporting portion, to snap a corresponding edge of the daughter card.

5. The circuit board assembly of claim 1, wherein, the daughter card is an embedded universal serial bus daughter card.

6. A connecting bracket used to connect a circuit board to a daughter card, the circuit board comprising a first connector and a first position element, the daughter card comprising a second connector compatible with the first connector and a second position element corresponding to the first position element, the connecting bracket comprising:
a supporting portion, wherein a first connecting portion extends down from the supporting portion, a second connecting portion extends up from the supporting portion and is electrically connected to the first connecting portion, a first position portion and a second position portion extend from the supporting portion;
wherein the first connector of the circuit board is connected to the first connecting portion of the connecting bracket, the second connector of the daughter card is connected to the second connecting portion of the connecting bracket, the first position element of the circuit board is latched with the first position portion of the connecting bracket, the second position element of the daughter card is latched with the second position portion of the connecting bracket.

7. The connecting bracket of claim 6, wherein an L-shaped elastic fixing portion extends up from an edge of the supporting portion, to snap a corresponding edge of the daughter card.

8. The connecting bracket of claim 6, wherein each of the first and second position portions comprises two opposite elastic latching posts extending from distal ends of the first and second position portions of the connecting bracket, with a groove defined between the latching posts.

9. The connecting bracket of claim 6, wherein the first connecting portion and the second connecting portion extend from a first end of the supporting portion.

10. The connecting bracket of claim 9, wherein the first and second position portions extend from a second end of the supporting portion opposite to the first end.

11. The connecting bracket of claim 9, wherein an L-shaped elastic fixing portion extends up from the first end of the supporting portion, to snap a corresponding edge of the daughter card.
